(19) United States
(12) Patent Application Publication
(10) Pub. No.: US 2026/0352215 A1
(43) Pub. Date: Nov. 5, 2026

(54) Method and Apparatus of Providing A Lookup Table Structure, Programmable Logic Unit, and FPGA Device

(71) Applicant: Shanghai Singate Semiconductor Corp., Shanghai (CN)

(72) Inventors: Qiming Wu, Shanghai (CN); Xiaozhi Lin, Shanghai (CN); Tianping Wang, Shanghai (CN); Tainxin Wang, Shanghai (CN); Bo Chu, Shanghai (CN)

(73) Assignee: Shanghai Singate Semiconductor Corp., Shanghai (CN)

(21) Appl. No.: 19/417,372

(22) Filed: Dec. 12, 2025

(30) Foreign Application Priority Data
Feb. 20, 2025 (CN) 202510194303.X

(51) Int. Cl. H03K 19/17728; H03K 17/00; H03K 19/17736; H03K 19/21

(52) U.S. Cl. CPC H03K 19/17728; H03K 17/005; H03K 19/1774; H03K 19/17744; H03K 19/21

(57) ABSTRACT

A lookup table structure, programmable logic unit and FPGA device, wherein the lookup table structure comprises four 4-input lookup tables lut 4_1, lut 4_2, lut 4_3, and lut 4_4, and three multiplexers mux 4, mux 5, and mux 7. When the lookup table structure is in 6-input lookup table mode, each 4-input lookup table receives the 4-bit data signal IN0 from the 6-input lookup table and outputs the respective output signal. The output signals of lut 4_1 and lut 4_2 are the input signals of mux 4; the output signals of lut 4_3 and lut 4_4 are the input signals of mux 5. With the control of the fifth data signal in the 6-input lookup table, mux 4 and mux 5 respectively output signals based on the input signals, which serve as the input signals of mux7. With the control of the sixth data signal in the 6-input lookup table, mux 7 output signals based on the received input signals, which serve as the output results of the 6-input lookup table. The lookup table structure features configurable functionalities and offers flexible logic implementation and computational capabilities.

### PRIORITY

This application claims the benefit of priority of an earlier filed Chinese patent application with a Ser. No. 202510194303.X, filed on Feb. 20, 2025 with China National Intellectual Property Administration of the People's Republic of China, having a title of “A Lookup Table Structure, Programmable Logic Unit, and FPGA Device,” the disclosure of which is hereby incorporated by reference.

### FIELD

The present invention relates to integrated circuit technology, in particular an LUT structure, a PLU, and an FPGA device.

### BACKGROUND

An FPGA is a semi-custom integrated circuit (IC). Compared with Application-Specific Integrated Circuits (ASICs), FPGAs offer higher flexibility. Through hardware description language synthesis, circuit designs can be rapidly implemented via FPGAs, shortening the R&D design process.

In an FPGA, a PLU consists of two parts: a programmable function unit and a programmable interconnect unit. The programmable function unit includes LUT structures, addition-subtraction carry chains, and sequential logic units. An N-input LUT structure is capable of implementing any N-input combination logic, for example, the LUT4 with a 4-input LUT structure and the LUT6 with a 6-input LUT structure. Generally, for small-scale FPGAs, 4-input LUT structure has better logic resource utilization efficiency, while for larger FPGAs or more complex logic, because of the complexity of routing resources, the LUT structure with more input is preferred, such as LUT6 structure.

The FPGA is a type of logic device with abundant hardware resources, powerful parallel processing, and flexible reconfigurability. Due to these characteristics, FPGAs have been increasingly and widely applied in various fields such as data processing, communications, and networking.

With the enhancement of system functionality and the expansion of system scale, the number of logic gates required in programmable logic devices has been steadily increasing, as exemplified by the extensively application of FPGAs with tens of millions of gates. As the number of FPGA gates increases, the functional implementation capability and logic capacity of FPGAs are enhanced; however, such growth also leads to a corresponding degradation in performance. For example, larger chip areas, higher power consumption, and reduced operating speed may occur, which limit the overall system performance. Therefore, in addition to reducing process dimensions and increasing the number of logic gates, it is also necessary to enhance the utilization capability of each logic block.

Enhancing the flexibility of LUT structure, logic implementation, and computational capabilities, effectively improves the utilization efficiency of routing resources, reduces the resource utilization area, and increases the operating speed of the chip, thus facilitating more functions and applications with limited resources.

### SUMMARY

The embodiment of the present application relates to relates to an LUT structure, PLU, and an FPGA device.

An LUT structure, comprising four 4-input LUTs lut 4_1, lut 4_2, lut 4_3, and lut 4_4; and three multiplexers mux 4, mux 5, and mux 7;
wherein when the LUT structure is in 6-input LUT mode, each 4-input LUT receives the 4-bit data signal IN0 from the 6-input LUT and outputs the respective output signal. The output signals of lut 4_1 and lut 4_2 are the input signals of mux 4; the output signals of lut 4_3 and lut 4_4 are the input signals of mux 5.
wherein with the control of the fifth data signal in the 6-input LUT, mux 4 and mux 5 respectively output signals based on the input signals, serving as the input signals for mux7;
wherein with the control of the sixth data signal in the 6-input LUT, mux 7 output signals based on the received input signals, serving as the output results of the 6-input LUT.

A PLU, comprising the LUT structure and the carry chain structure, wherein the carry chain structure comprising four cascaded algorithm logic units (ALUs), each ALU comprising a corresponding 4-input LUT; wherein each ALU receives corresponding carry input signal and 4-input LUT output signal and outputs signals.

An FPGA device comprising the above-described LUT structure or the PLU.

The embodiment of the present application uses four LUT4s to implement LUT6 function, which is capable of facilitating the logic function of one 6-input LUT or two 5-input LUT or four 4-input LUTs. The embodiment of the present application has a higher flexibility. Choosing different LUT structure modes in different application scenarios to facilitate flexible logic implementation and computational capabilities is able to effectively improve the utilization efficiency of routing resources, reduce the resource utilization area, and increase the operating speed of the chip, thus facilitating more functions and applications with limited resources.

Additional features and benefits of the exemplary embodiment(s) of the present application will become apparent from the detailed description, figures, and claims set forth below. Additional benefits of the application can be realized and obtained through the solutions described in the detailed description and drawings.

### BRIEF DESCRIPTION OF THE DRAWINGS

The exemplary embodiment(s) of the present invention will be understood more fully from the detailed description given below and from the accompanying drawings of various embodiments of the invention, which, however, should not be taken to limit the invention to the specific embodiments, but are for explanation and understanding only.

FIG. 1 is a diagram illustrating the internal structure of LUT4;

FIG. 2 is a diagram illustrating the truth table of LUT4 shown in FIG. 1;

FIG. 3 is a diagram illustrating the Karnaugh map corresponding to the truth table shown in FIG. 2;

FIG. 4 is a diagram illustrating the LUT structure in accordance with the embodiment of the present invention;

FIG. 5 is a diagram illustrating the LUT structure in 4-input LUT mode shown in FIG. 4;

FIG. 6 is a diagram illustrating the LUT structure in 5-input LUT mode shown in FIG. 4;

FIG. 7 is a diagram illustrating the LUT structure in 6-input LUT mode shown in FIG. 4;

FIG. 8 is a diagram illustrating the connection of the LUT structure and the carry chain structure in accordance with the embodiment of the present invention;

FIG. 9 is a diagram illustrating the structure of LUT4 shown in FIG. 8;

FIG. 10 is a diagram illustrating the structure of LUT2 in accordance with the embodiment of the present invention;

FIG. 11 is a diagram illustrating the structure of the PLU in accordance with the embodiment of the present invention;

FIG. 12 is a diagram illustrating the deployment of the FPGA device in accordance with the embodiment of the present invention;

FIG. 13 is a diagram illustrating the routing deployment of the LUT in the FPGA device in accordance with the embodiment of the present invention;

FIG. 14 is a diagram illustrating the application of the structure shown in FIG. 13;

FIG. 15 is a diagram illustrating the deployment of the structure shown in FIG. 14;

FIG. 16 is a diagram illustrating the signal flow of the structure in LUT6 mode shown in FIG. 15;

FIG. 17 is a diagram illustrating the signal flow of the structure in LUT5 mode shown in FIG. 15;

FIG. 18 is a diagram illustrating the operating mode of the MUX in the structure shown in FIG. 15;

FIG. 19 is the first diagram illustrating the signal flow in the structure shown in FIG. 18;

FIG. 20 is the second diagram illustrating the signal flow in the structure shown in FIG. 18;

FIG. 21 is the third diagram illustrating the signal flow in the structure shown in FIG. 18.

### DETAILED DESCRIPTION

Embodiments of the present invention disclose a circuitry, method, computer storage medium and terminal for deskew processing.

The present application describes multiple embodiments, but the description is exemplary and not limiting, and it will be obvious to those of ordinary skill in the art that there can be more embodiments within the scope of the embodiments described in the present application. Although many possible combinations of features are illustrated in the drawings and discussed in the detailed description, many other combinations of the disclosed features are possible. Unless specifically limited, any feature or element of any embodiment may be combined with any other feature or element of any other embodiment, or may substitute for any other feature or element of any other embodiment.

The present application includes and contemplates combinations with features and elements known to those of ordinary skill in the art. The embodiments, features, and elements that have been disclosed in the present application may also be combined with any conventional features or elements to form a unique invention. Any feature or element of any embodiment may also be combined with features or elements from other invention embodiments to form another unique invention embodiment. Accordingly, it should be understood that any of the features illustrated and/or discussed in this application may be realized individually or in any proper combination. Accordingly, In addition to the limitations imposed in accordance with the appended claims and their equivalents, no other limitations are placed on the embodiments. In addition, various modifications and changes may be made within the protection scope of the appended claims.

Furthermore, in describing representative embodiments, the detailed description may have presented the method and/or process as a particular sequence of steps. However, to the extent that the method or process does not depend on a particular sequence of steps described herein, the method or process should not be limited to the particular sequence of steps described. As those of ordinary skill in the art will understand, other sequence of steps is possible. Thus, the particular sequence of steps set forth in the detailed description should not be construed as a limitation of the claims. Furthermore, the claims directed to the method and/or process should not be limited to the steps of performing them in the order in which they are written, and it can be readily understood by those of ordinary skill in the art that these orders can be varied and still remain within the spirit and scope of the embodiments of the present application.

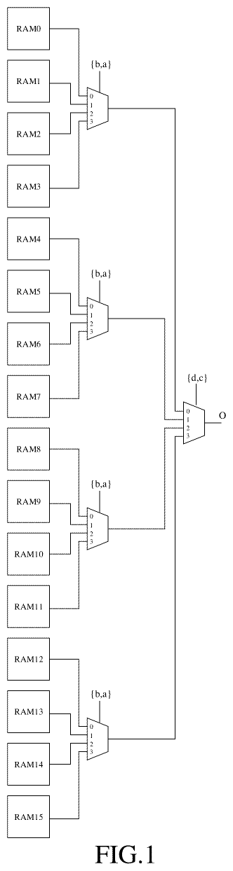

FIGS. 1 to 3 collectively illustrate the operating principle and logic implementation of the LUT4 in the FPGA device.

FIG. 1 is a diagram illustrating the structure of LUT4. As shown in FIG. 1, the LUT4 consists of 16 memory cells (RAM0-RAM15) and five 4-to-1 multiplexers (MUXes). The input variables b and a are used to control the lower 4-to-1 MUX, determining which input channel is transmitted to the higher MUX. The input variables b and a are used to control the higher 4-to-1 MUX, determining which input channel of lower MUX is transmitted to the higher MUX. Specifically, When input {d,c,b,a} is 0000, the output of LUT4 is the value of RAM0; when input {d,c,b,a} is 0001, the output of LUT4 is the value of RAM1; when input {d,c,b,a} is 0010, the output of LUT4 is the value of RAM2; by analogy, when input {d,c,b,a} is 1111, the output of LUT4 is the value of RAM15; thus generating the final output of the LUT4.

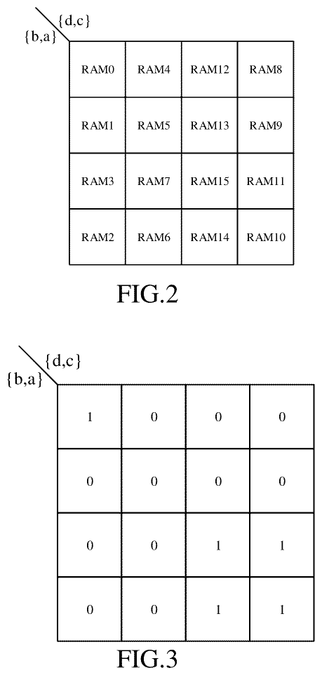

FIG. 2 is a diagram illustrating the truth table of LUT4 shown in FIG. 1. As shown in FIG. 2, the truth table shown in FIG. 2 lists all possible combinations of inputs (a, b, c, d) and the corresponding outputs. In the truth table, each row represents a unique combination of input variables a, b, c, d, and the column represents the output state of LUT4 under the input combination.

FIG. 3 is a diagram illustrating the Karnaugh map corresponding to the truth table shown in FIG. 2. The Karnaugh map is a graphical tool used to simplify a Boolean function. As shown in FIG. 3, in the Karnaugh map, each cell of RAM0 to RAM15 is capable of configuring as either 0 or 1 for implementing specific logic functions. For example, the configuration in FIG. 3 implements the logic function F=!(a+b+c+d)+(d&b),
wherein !(a+b+c+d) represents the negation of the logical OR of a, b, c, d, that is, when all inputs are 0, !(a+b+c+d) is 1;
d&b represents the logical AND of d and b, that is, when d and b are both 1, d&b is 1.

The entire expression F is the logical OR of both of the (a+b+c+d) and d&b, that is as long as either (a+b+c+d) or d&b is 1, the output F is 1. Properly configuring RAM cells in Karnaugh map is capable of implementing required logic functions.

This kind of configuration allows LUT4 to implement arbitrary 4-variable Boolean functions and is the basis for implementing complex logic circuits in FPGA devices. By properly configuring the LUT4, various logic functions can be effectively implemented to optimize circuit performance.

The LUT structure in accordance with the embodiment of the present invention uses four LUT4s to implement the functions of LUT5 and LUT6, and according to the required LUT, determine the mode of the LUT, so as to control the LUT structure to operate as LUT4 or LUT5 or LUT6.

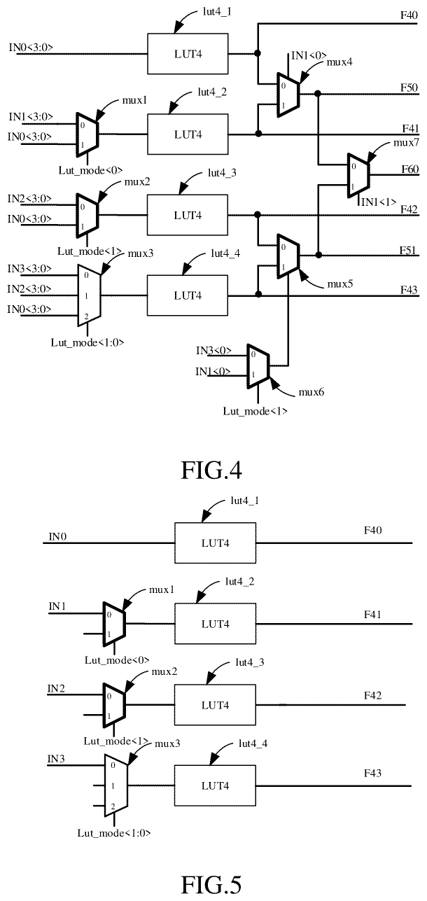

FIG. 4 is a diagram illustrating the LUT structure in accordance with the embodiment of the present invention. As shown in FIG. 4, the LUT structure consists of four 4-input LUT4s and seven MUXes. Specifically, the four LUT4 are respectively lut4_1, lut4_2, lut4_3, and lut4_4, while the seven MUXes are respectively mux1, mux2, mux3, mux4, mux5, mux6, and mux7.

The LUT structure in the embodiment can be configured in multiple modes, including one 6-input LUT mode, two 5-input LUT modes, four 4-input LUT modes, and a mode that simultaneously implements two 4-input LUTs and one 5-input LUT.

In the structure of FIG. 4, the input signals for each LUT4 are configured as follows:
lut4_1 receives IN0 directly as an input signal;
the input signal of lut4_2 can be selected from IN0 or IN1, the final selection is determined by mux1 according to the control signal Lut_mode<0>;
the input signal of lut4_3 can be selected from IN0 or IN2, the final selection is determined by mux2 according to the control signal Lut_mode<1>;
the input signal of lut4_4 can be selected from IN0, IN2, or IN3, and the final selection is determined by mux3 according to the control signal Lut_mode<1:0>.

IN0, IN1, IN2, and IN3 are all 4-bit data signals. For example, IN0 can be represented as a0, b0, c0, and d0; IN1 as a1, b1, c1, and d1; IN2 as a2, b2, c2, and d2; and IN3 as a3, b3, c3, and d3.

The output signals for each LUT4 are configured as follows:
the output signal of lut4_1 can be output independently (corresponding to F40 in FIG. 4) or as one-channel input signal of mux4;
the output signal of lut4_2 can be output independently (corresponding to F41 in FIG. 4) or as another channel input signal of mux4;
the output signal of lut4_3 can be output independently (corresponding to F42 in FIG. 4) or as one-channel input signal of mux5;
the output signal of lut4_4 can be independently output (corresponding to F43 in FIG. 4) or as another channel input signal of mux5;
In the structure of FIG. 4, the fifth data signal of the LUT structure is used to control mux4 and mux5:
in 5-input LUT mode, the fifth data signals corresponding to mux4 and mux5 have different values;
in 6-input LUT mode, the fifth data signals corresponding to mux4 and mux5 have identical values.

In the structure of FIG. 4, the value of the fifth data signal for mux4 is preset, and mux6 is used to control the value of the fifth data signal for mux5. Specifically, mux6 has two signal input terminals, one of which receives an identical value as the control terminal of mux4, the other receives a value different from the control terminal of mux4. The final output signal of mux6 is determined by the control signal Lut_mode<1>.

For example, when the fifth data signal corresponding to the control terminal of mux4 is a1, one signal input terminal of mux6 receives the data signal a1, while the other signal input terminal receives the data signal a3. When Lut_mode<1> indicates that the current LUT structure is in 5-input LUT mode, mux6 outputs a data signal a3; when Lut_mode<1> indicates that the current LUT structure is in 6-input LUT mode, mux6 outputs a data signal a1.

In the structure of FIG. 4, the output signal of mux4 can be independently output (corresponding to F50 in FIG. 4) or as one-channel input signal of mux7; the output signal of mux5 can be independently output (corresponding to F51 in FIG. 4) or as another channel input signal of mux7.

The mux7 receives the output signals of mux4 and mux5, and selects the output signal of mux4 or mux5 as the final output signal (corresponding to the F60 in FIG. 4) under the control of the sixth data signal of the LUT structure. This design enables the LUT structure to flexibly adapt to different modes and application requirements.

Taking the 4-input LUT mode of the LUT structure as an example for illustration:
FIG. 5 is a diagram illustrating the LUT structure in 4-input LUT mode shown in FIG. 4. In this mode, only three of the seven MUXes in the LUT structure are involved in operation, namely mux1, mux2, and mux3. The specific configuration is as follows:
The control signal lut_mode<0>=0 of mux1 select IN1 as the input signal of lut4_2;
The control signal lut_mode<1>=0 of mux2 select IN2 as the input signal of lut4_3;
The control signal lut_mode<1:0>=00 of mux3 select IN3 as the input signal of lut4_4.
Based on the above configuration, the four LUT4s operate as separate 4-input LUTs, as shown in FIG. 5:
lut 4_1 receives 4-bit data signal IN0 and outputs signal F40 as the output result of the first 4-input LUT;
lut 4_2 receives 4-bit data signal IN1 and outputs signal F41 as the output result of the second 4-input LUT;
lut 4_3 receives 4-bit data signal IN2 and outputs signal F42 as the output result of the third 4-input LUT;
lut 4_4 receives 4-bit data signal IN3 and outputs signal F43 as the output result of the fourth 4-input LUT;
If IN0 is represented as a0, b0, c0, and d0, IN1 as a1, b1, c1, and d1, IN2 as a2, b2, c2, and d2, and IN3 as a3, b3, c3, and d3, the input and output signals of the four independently operating LUT4 are as follows:
The input signals of the first LUT4 (lut4_1) are a0, b0, c0, and d0, and the output signal is F40;
The input signals of the second LUT4 (lut4_2) are a1, b1, c1, and d1, and the output signal is F41;
The input signals of the third LUT4 (lut4_3) are a2, b2, c2, and d2, and the output signal is F42;
The input signals of the fourth LUT4 (lut4_4) are a3, b3, c3, and d3, and the output signal is F43.

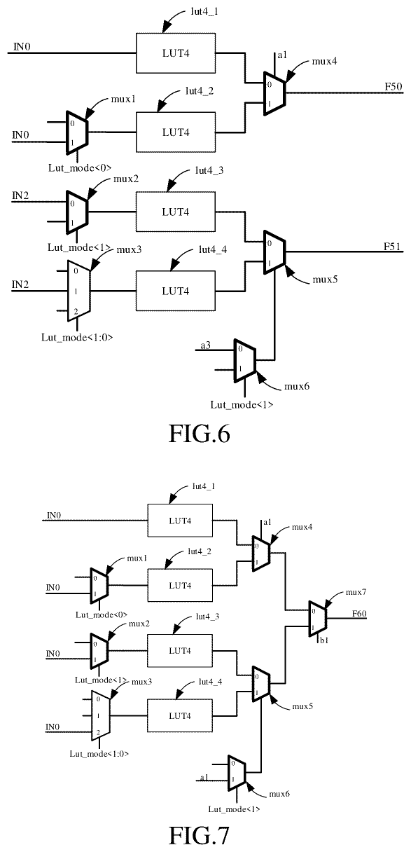

Taking the 5-input LUT mode as an example for illustration:
FIG. 6 is a diagram illustrating the LUT structure in 5-input LUT mode shown in FIG. 4; In this mode, all of the seven MUXes except for mux7 in the LUT structure are involved in operation. The specific configuration is as follows:
The control signal lut_mode<0>=1 of mux1 selects IN0 as the input signal of lut4_2;
The control signal lut_mode<1>=0 of mux2 selects IN2 as the input signal of lut4_3;
The control signal lut_mode<1:0>=01 of mux3 selects IN2 as the input signal of lut4_4;
The control signal lut_mode<1>=0 of mux6 selects a3 as the control signal of mux5 and the fifth data signal of the second LUT5, while the control signal of mux4 is a1, which serves as the fifth data signal of the first LUT5.

Based on the above configuration, the four LUT4s operate as two separate 5-input LUTs, as shown in FIG. 6:
lut4_1 and lut4_2 each receive 4-bit data signals IN0 and output the corresponding signals; mux4 receives output signals of lut4_1 and lut4_2 and outputs signals based on the received input signals, which serve as the output result F50 of the first 5-input LUT, with the control of the fifth data signal a1 in the first 5-input LUT;
lut4_3 and lut4_4 each receive 4-bit data signals IN2 and output the corresponding signals; mux5 receives output signals of lut4_3 and lut4_4 and outputs signals based on the received input signals, which serve as the output result F51 of the second 5-input LUT, with the control of the fifth data signal a3 in the second 5-input LUT;
If IN0 is represented as a0, b0, c0, and d0, IN2 as a2, b2, c2, and d2, the input signals of the two independently operating LUT5s are as follows:
The 5-input data signals of the first LUT5 are a0, b0, c0, d0, and a1, and the output signal is F50;
The 5-input data signals of the second LUT5 are a2, b2, c2, d2, and a3, and the output signal is F51;
Taking the 6-input LUT mode as an example for illustration:
FIG. 7 is a diagram illustrating the LUT structure in 6-input LUT mode shown in FIG. 4; In this mode, all of the seven MUXes in the LUT structure are involved in operation. The specific configuration is as follows:
The control signal lut_mode<0>=1 of mux1 select IN0 as the input signal of lut4_2;
The control signal lut_mode<1>=1 of mux2 select IN0 as the input signal of lut4_3;
The control signal lut_mode<1:0>=10 of mux3 select IN0 as the input signal of lut4_4;
The control signal lut_mode<1>=1 of mux6 selects a1 as the control signal of mux5 and the fifth data signal of LUT6, remaining consistent with the control signal a1 of mux4.

Based on the above configuration, the four LUT4s operate as one 6-input LUT, as shown in FIG. 7:
Each of lut4_1, lut4_2, lut4_3, and lut4_4 receives 4-bit data signal IN0 and outputs the corresponding signals. The output signals of lut 4_1 and lut 4_2 are the input signals of mux4, while the output signals of lut 4_3 and lut 4_4 are the input signals of mux 5;
With the control of the fifth data signal a1, mux 4 and mux 5 respectively output signals based on the input signals, which serve as the input signals for mux 7;
With the control of the sixth data signal b1, mux 7 signals output signals based on the received input signals, which serve as the output results F60 of the 6-input LUT.

If IN0 is represented as a0, b0, c0, and d0, the 6-bit data signals of LUT6 are a0, b0, c0, d0, a1, and b1, and the output signal is F60.

By comparing the structures shown in FIGS. 5 to 7, it can be seen that the structure shown in FIG. 5 has sixteen input terminals to receive four LUT4 data signals, the structure shown in FIG. 6 has ten input terminals to receive two LUT5 data signals, and the structure shown in FIG. 7 has six inputs to receive one LUT6 data signal. As the number of input terminals decreases, the required routing resources are reduced, making the structure more suitable for large-scale programmable applications. For example, the structure shown in FIG. 5 has more flexible programmable features, the structure shown in FIG. 6 is more suitable for medium-scale programming applications, and the structure shown in FIG. 7 is more suitable for large-scale programming applications.

In practical applications, when programmable logic is hierarchically divided from the top-level circuit, it is generally divided into large-scale, medium-scale, and small-scale logic. Based on the characteristics of programming, choosing appropriate LUT structure mode according to the different scale of programmable logic can simultaneously balance routing resources and programmable logic resources, thus achieving a good trade-off between routing resources and programmable logic resources.

Alternatively, this application provides a PLU, including the above-described LUT, carry chain structure, and sequential logic unit.

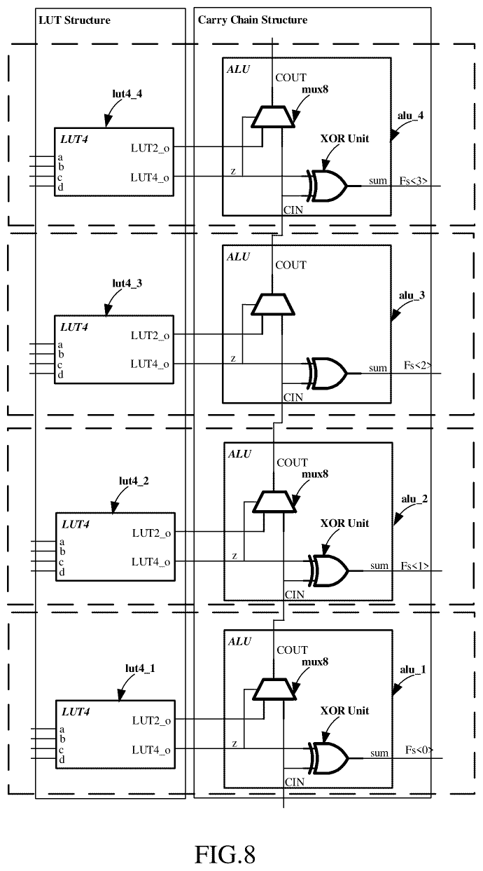

The following describes the carry chain structure:
FIG. 8 is a diagram illustrating the connection of the LUT structure and the carry chain structure in accordance with the embodiment of the present invention. As shown in FIG.
8, the carry chain structure consists of four cascaded ALUs, including alu_1, alu_2, alu_3, and alu_4.

Each ALU has a corresponding 4-input LUT (LUT4). In the structure shown in FIG. 8, alu_1 is associated with lut4_1, alu_2 is associated with lut4_2, alu_3 is associated with lut4_3, and alu_4 is associated with lut4_4. Each ALU receives its corresponding carry input signal and 4-input LUT output signal and outputs the corresponding result signal.

In the structure shown in FIG. 8, each ALU is equipped with an LUT4, which enables each ALU to cooperate with other ALUs as well as operate independently.

Specifically, each ALU consists of a multiplexer mux 8 and an exclusive OR (XOR) unit;
wherein, for the current ALU, mux 8 receives the carry input signal CIN of the current ALU and the output signal LUT2_o of the 2-input lookup table logic of the current ALU's 4-input lookup table. With the control of the output signal LUT4_o of the 4-input lookup table logic of the current ALU's 4-input lookup table, mux 8 outputs the carry output signal COUT of the current ALU, which serves as one of the output signals of the current ALU.
wherein, for the current ALU, the XOR unit receives the carry input signal CIN of the current ALU and the output signal LUT4_o of the 4-input lookup table logic of the current ALU's 4-input lookup table and outputs the computation result signal Fs, which serves as one of the output signal of the current ALU.

As can be seen from the above, if the current ALU operates independently, the XOR unit can be used as an adder or subtractor to operate, if the current ALU cooperate with other ALUs, the mux8 can be used to output their corresponding carry output signals, cascading into multiple-bit adder or subtractor to operate.
alu_1 can use the internal mux8 to output carry output signal COUT or use the internal XOR unit to output computation result signal Fs<0>.
alu_2 can receive the carry output signal COUT from alu_1 as the carry input signal CIN and use the internal mux 8 to output carry output signal COUT or the use the internal XOR unit to output computation result signal Fs<1>.
alu_3 can receive the carry output signal COUT from alu_2 as the carry input signal CIN and use the internal mux 8 to output carry output signal COUT or the use the internal XOR unit to output computation result signal Fs<2>.
alu_4 can receive the carry output signal COUT from alu_3 as the carry input signal CIN and use the internal mux 8 to output carry output signal COUT or the use the internal XOR unit to output computation result signal Fs<3>.

In practical applications, some ALUs within the carry chain can be selectively enabled to perform computation operations according to implementation requirements. For example, only alu_1 may be enabled, or only alu_1 and alu_2, or only alu_1, alu_2, and alu_3, thereby achieving efficient utilization of resources and reducing waste; alternatively, multiple ALUs can be cascaded to form a multi-bit arithmetic unit.

In ALU, the processing logic of the XOR unit is sum[i]=LUT4[i]\hat{ }Carry[i−1], indicating that the sum output of the i-th bit is obtained by performing an XOR operation between the LUT4 logic output of the i-th bit (LUT4[i]) and the carry of the previous bit (Carry[i−1]). The processing logic of mux 8 is Carry[i]=LUT4[i]*Carry[i−1]+(! LUT4[i])*LUT2[i], indicating that the carry of the i-th bit is obtained by performing an AND operation between the LUT4 logic output of the i-th bit and the carry of the previous bit, and then plus the LUT2 logic output of the i-th bit, wherein i is a positive integer.

When adder function is implemented, LUT4[i]=a[i]\hat{ }b[i]; LUT2[i]=a[i] or b[i]; Carry[0]=0.

When subtractor function is implemented, LUT4[i]=a[i]\hat{ }(!b[i]), LUT2[i]=a[i], or !b[i]; Carry[0]=1.

In the structure shown in FIG. 8, z indicates the processing result for LUT4_o.

In the structure shown in FIG. 8, the LUT structure and the carry chain structure can form the basic unit of the adder or subtractor. The cascades of the multiple basic units can form higher-bit adders and subtractors.

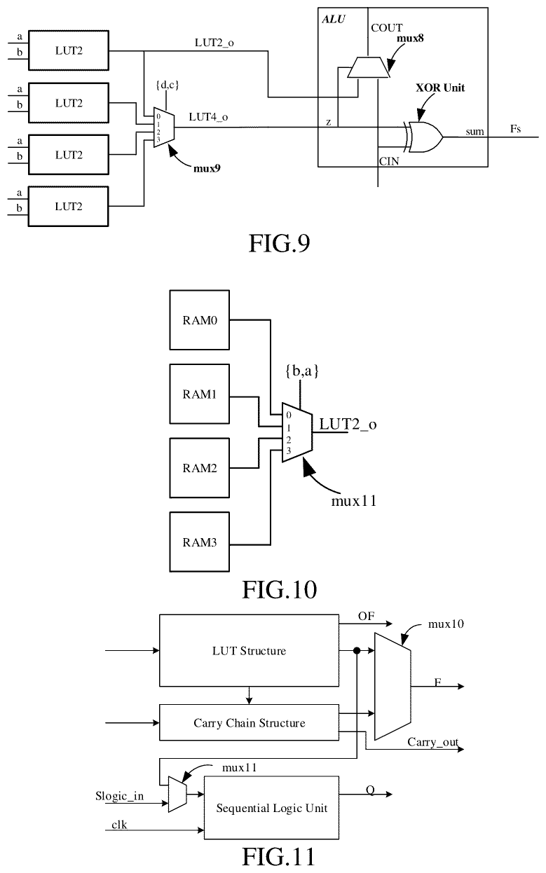

FIG. 9 is a diagram illustrating the structure of LUT4 shown in FIG. 8. As shown in FIG. 9, the 4-input LUT consists of multiplexer mux 9 and four 2-input LUTs,
wherein each 2-input LUT (LUT2) receives the data signals of the two signal input terminals among the four signal input terminals of the 4-input LUT and outputs respective output signals, wherein the output signal of one of the 2-input lookup tables is output to the corresponding ALU.
wherein mux 9 receives the output signals of four 2-input LUTs and outputs signals, which serve as the output results LUT4_o of the 4-input LUT logic, with the control of the data signals of the remaining two signal input terminals among the four signal input terminals of the 4-input LUT. In the structure shown in FIG. 9, the output signals of four LUT2s are the input signals of mux 9, and with the control of the 2-bit data signals {c, d}, mux 9 outputs signal LUT4_o.

FIG. 10 is a diagram illustrating the structure of LUT2 in accordance with the embodiment of the present invention. As shown in FIG. 10, within each LUT2, the data stored in the four RAMs (RAM0, RAM1, RAM2, RAM3) is used as the input signals of mux 11. With the control of 2-bit data signals {a, b}, mux 11 generates the output signal LUT2_o. Specifically, when LUT2[i]=a is implemented, the RAM is set to RAM0=0, RAM1=1, RAM2=0, RAM3=1, while when LUT2[i]=b is implemented, the RAM is set to RAM0=0, RAM1=0, RAM2=1, RAM3=1.

FIG. 11 is a diagram illustrating the structure of the PLU in accordance with the embodiment of the present invention. As shown in FIG. 11, the output signals of the LUT structure can be independent outputs (corresponding to the OF signal in the FIG. 11), and the output signals of the carry chain structure can also be independent outputs (corresponding to the Carry_out signal in FIG. 11).

Alternatively, the PLU comprises a multiplexer mux 10. The mux 10 receives the output signal of the LUT structure and the output signal of the carry chain structure, and selects one of the output signals as the output signal of PLU as required (corresponding to the F signal in FIG. 11).

The PLU further comprises a sequential logic unit. With the control of the clock signal clk, the sequential logic unit uses the input signal to generate the output signals (corresponding to the Q signal in FIG. 11). The input signal of the sequential logic unit can be the output signal of the LUT structure or a preset sequential input signal (corresponding to the slogic_in signal in FIG. 11).

Specifically, the PLU further comprises a multiplexer mux 11. The mux 11 receives the output signal and sequential input signal of the LUT structure and selects one of the signals as the input signal of sequential logic unit as required. Such a design allows flexible control of the behavior of the sequential logic unit to accommodate different logic requirements.

Alternatively, the embodiment of the present application relates to an FPGA device comprising the above-described LUT structure or PLU.

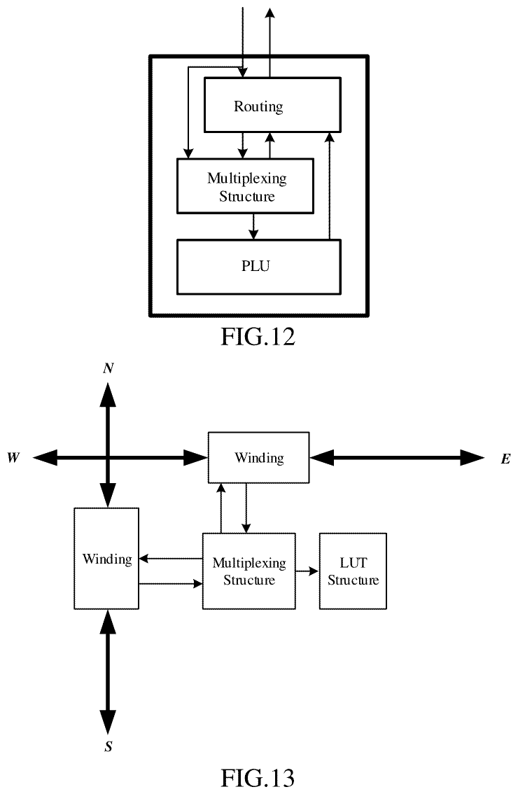

FIG. 12 is a diagram illustrating the deployment of the FPGA device in accordance with the embodiment of the present invention. As shown in FIG. 12, the FPGA device includes east-west (EW) and north-south (SN) routing channels, as indicated by the arrows in FIG. 12. These channels are used to provide the required data signals and clock signals to the PLU. The multiplexing structure is used to transmit data signals and clock signals on the routing channels to the PLU.

FIG. 13 is a diagram illustrating the routing deployment of the LUT in the FPGA device in accordance with the embodiment of the present invention. As shown in FIG. 13, the input signal of the LUT structure is from the output of the multiplexing structure in FIG. 12. The input of the LUT structure can be a combination logic of 4-input, 5-input, or 6-input.

When the LUT structure is in LUT5 mode, since only IN0, IN2, the first bit of IN1, and the first bit of IN3 are selected as inputs, the remaining MUXes of IN1 and IN3 can serve as interconnection bridges between routing paths. This enables interconnection between north-south routing buses, between east-west routing buses, or between north-south and east-west routing buses.

When the LUT structure is in LUT6 mode, since only IN0, the first and second bit of IN1 are selected as inputs, the remaining MUXes of IN1, IN2, and IN3 can serve as interconnection bridges between routing paths, achieving a similar interconnection function.

In practical applications, users can choose different LUT modes according to the logic scale and routing complexity, to achieve optimal logic resource utilization and routing interconnectivity.

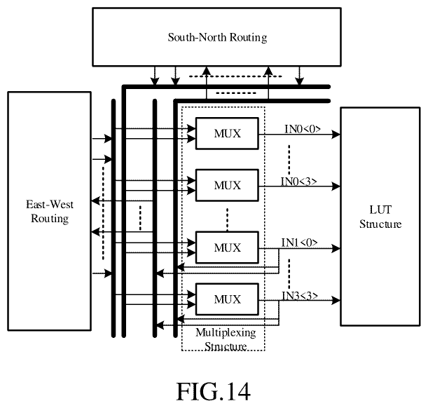

FIG. 14 is a diagram illustrating the application of the structure shown in FIG. 13. As shown in FIG. 14, the FPGA device is configured with a multiplexing structure, wherein the multiplexing structure input buses are connected to the east-west routing output bus and the south-north routing output bus respectively, while the output bus is connected to the LUT structure, and at the same time, the output terminal is connected to the east-west routing input bus and the south-north routing input bus. The multiplexing structure obtaining data signals from the east-west and north-south routing input bus to output the received signals to the LUT structure as the data signals of the LUT structure in different modes. In the 6-input or 5-input LUT mode, part of the multiplexing structure can be used as a bridge, connecting north-south or east-west routing signals. For example, in 6-input LUT mode, the multiplexing structures corresponding to IN1<2>, IN1<3>, IN2<0>, IN2<1>, IN2<2>, IN2<3>, IN3<0>, IN3<1>, IN3<2>, and IN3<3> can be used as bridges. For example, in 5-input LUT mode, the multiplexing structures corresponding to IN1<1>, IN1<2>, IN1<3>, IN3<1>, IN3<2>, and IN3<3> can be used as bridges.

The data signals from the east-west routing and the south-north routing are selected through the MUX in the multiplexing structure, then transmitted into IN0<0> through IN3<3>, finally into the LUT. In LUT5 and LUT6 modes, the remaining input MUX, such as MUX of IN1<2>, can be used as bridging MUX to connect to east-west and north-south bridge buses for east-west and north-south routing interconnectivity.

In logic programming with smaller logic scale, the maximum utilization of logic resources can be achieved by configuring the LUT4 mode. In logic programming with larger logic scale, the maximum utilization of routing resources can be achieved.

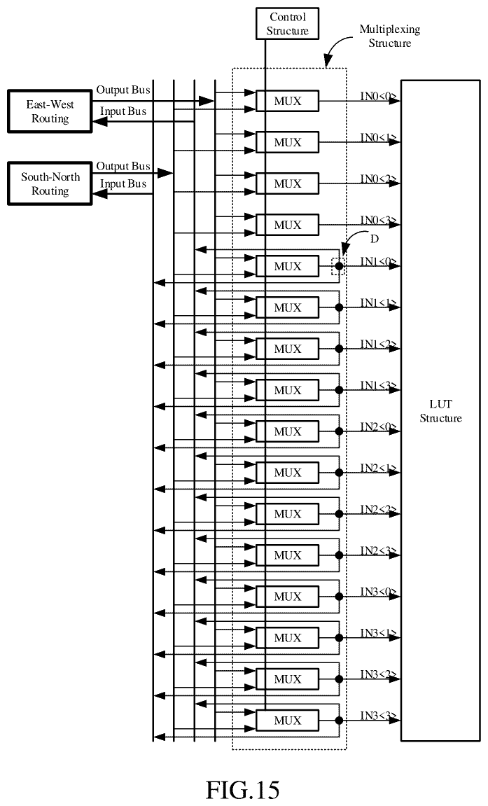

FIG. 15 is a diagram illustrating the deployment of the structure shown in FIG. 14. As shown in FIG. 15, the LUT structure has 4-channel 4-bit data signal input terminals, a total of 16 signal input terminals, including the signal input terminals of IN0<0>, IN0<1>, IN0<2>, IN0<3>, IN1<0>, IN1<1>, IN1<2>, IN1<3>, IN2<0>, IN2<1>, IN2<2>, IN2<3>, IN3<0>, IN3<1>, IN3<2>, and IN3<3>.

In the structure shown in FIG. 15, the multiplexing structure consists of the MUXes corresponding to each signal input terminal, wherein each MUX can obtain the corresponding data signal from the output buses of the east-west and north-south routings, and with the control of the control signal transmitted by the control structure, select one signal as the data signal of the corresponding signal input terminal.
wherein three 4-bit data signals IN1, IN2, and IN3 comprise a total of 12 signal input terminals corresponding to 12 MUXes. Each output terminal of these 12 MUXes is connected to the corresponding signal input terminal via a connection point. These connection points is connected to two sub-routes within the east-west routing input bus, or to two sub-routes within the north-south routing input bus, or respectively to one sub-route within the east-west routing input bus and one sub-route within the north-south routing input bus.
wherein when any signal input terminal in the LUT structure does not require an input signal, the MUX corresponding to that signal, which is not involved in the LUT operation, acts as a bridging MUX. The bridging MUX outputs the received signal through the connection point to the sub-routes of the respective north-south and east-west routing input buses.

Specifically, MUXes corresponding to the signal input terminals of IN1<0> through IN1<3>, IN2<0> through IN2<3>, and IN3<0> through IN3<3> can also be used as bridging MUXes. In the structure shown in FIG. 15, connection points D are set between these MUXes and the corresponding signal input terminals, wherein the connection point D is respectively connected to one sub-route of the input bus of the east-west routing and one sub-route of the input bus of the south-north routing, so that the MUX output signals can be input through the east-west routing input bus or the south-north routing input bus.

In the structure shown in FIG. 15, the output terminal of the bridging MUX is respectively connected to one sub-route of the input bus of the east-west routing and one sub-route of the input bus of the south-north routing, but not limited to this, in practical applications, the output terminal of the bridging MUX can respectively connect to two sub-routes of the input bus of the east-west routing or two sub-routes of the input bus of the south-north routing.

When the LUT structure is in 6-input LUT mode, the MUXes corresponding to four signal input terminals of 4-bit data signals IN0 receive the 4-bit data signal in 6-input LUT mode from the respective input terminals and output the signal through the respective output terminals; Among the twelve signal input terminals of three 4-bit data signals IN1, IN2, and IN3, the MUXes corresponding to two of the signal input terminals receive the fifth and sixth data signals in 6-input look-up table mode from the respective input terminals and output the signals through the respective output terminals.

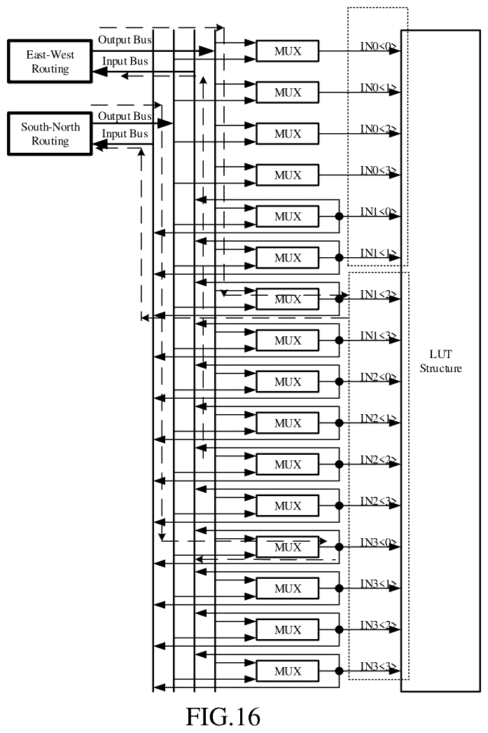

FIG. 16 is a diagram illustrating the signal flow of the structure in LUT6 mode shown in FIG. 15. As shown in FIG. 16, the signal input terminals of IN0<0>, IN0<1>, IN0<2>, IN0<3>, IN1<0>, and IN1<1>, a total of six signal input terminals, are used as the signal input terminals of the LUT6. The remaining signal input terminals are not involved in the operation of the LUT structure, thus, the MUXes corresponding to the remaining signal input terminals can be used as bridging MUXes.

For example, the structure shown in FIG. 16 comprises the MUX corresponding to the signal input terminal of IN1<2> and the MUX corresponding to the signal input of IN3<0>,
wherein, for the MUX corresponding to the signal input terminal of IN1<2>, the MUX receives the signal from the output bus of the east-west routing and transmits the received signal to the input bus of the north-south routing via connection point D.
wherein, for the MUX corresponding to the signal input terminal of IN3<0>, the MUX receives the signal from the output bus of the north-south routing and transmits the received signal to the input bus of the east-west routing via connection point D.

It can be seen from the above examples that the bridging MUX enables the interconnection between signals transmitted by the bus of the east-west routing and signals transmitted by the bus of the north-south routing.

When the LUT structure is in 5-input LUT mode, the MUXes corresponding to four signal input terminals of 4-bit data signals IN0 receive the 4-bit data signal of the first 5-input LUT from the respective input terminals and output the signal through the respective output terminals; the MUXes corresponding to four signal input terminals of 4-bit data signals IN2 receive the 4-bit data signal of the second 5-input LUT from the respective input terminals and output the signal through the respective output terminals; Among the eight signal input terminals of two 4-bit data signals IN1 and IN3, the MUXes corresponding to two of the signal input terminals respectively receive the fifth data signal of the first and second 5-input LUT from the respective input terminals and output the signals through the respective output terminals.

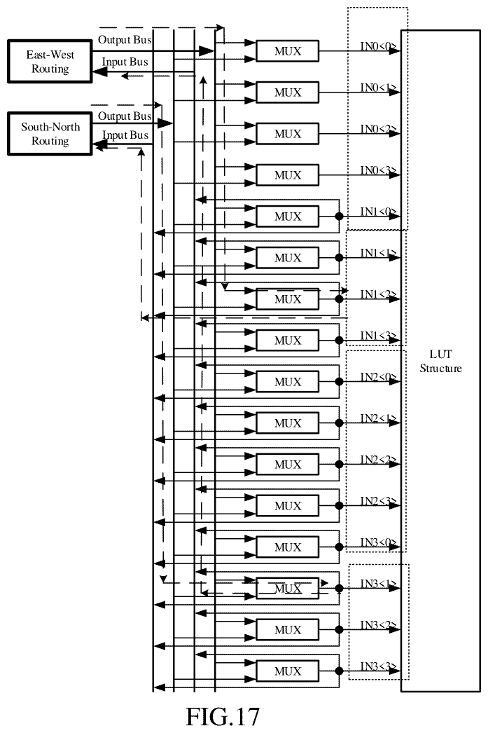

FIG. 17 is a diagram illustrating the signal flow of the structure in LUT5 mode shown in FIG. 15. As shown in FIG. 17, the signal input terminals of IN0<0>, IN0<1>, IN0<2>, IN0<3>, and IN1<0>, a total of five signal input terminals, are used as the signal input terminal of the first LUT5. The signal input terminals of IN2<0>, IN2<1>, IN2<2>, IN2<3>, and IN3<0>, a total of five signal input terminals, are used as the signal input terminal of the second LUT5. The remaining signal input terminals are not involved in the operation of the LUT structure, thus, the MUXes corresponding to the remaining signal input terminals can be used as bridging MUXes.

For example, the structure shown in FIG. 17 comprises the MUX corresponding to the signal input terminal of IN1<2> and the MUX corresponding to the signal input of IN3<1>,
wherein, for the MUX corresponding to the signal input terminal of IN1<2>, the MUX receives the signal from the output bus of the east-west routing and transmits the received signal to the input bus of the north-south routing via connection point D.
wherein, for the MUX corresponding to the signal input terminal of IN3<1>, the MUX receives the signal from the output bus of the north-south routing and transmits the received signal to the input bus of the east-west routing via connection point D.

It can be seen from the above examples that the bridging MUX enables the interconnection between signals transmitted by the bus of the east-west routing and signals transmitted by the bus of the north-south routing.

Similarly, when the LUT structure is in 4-input LUT mode, the MUXes corresponding to four signal input terminals of 4-bit data signals IN0 receive the 4-bit data signal of the first 4-input LUT from the respective input terminals and output the signal through the respective output terminals; the MUXes corresponding to four signal input terminals of 4-bit data signals IN1 receive the 4-bit data signal of the second 4-input LUT from the respective output terminals and output the signal through the respective output terminals; the MUXes corresponding to four signal input terminals of 4-bit data signals IN2 receive the 4-bit data signal of the third 4-input LUT from the respective output terminals and output the signal through the respective output terminals; the MUXes corresponding to four signal input terminals of 4-bit data signals IN3 receive the 4-bit data signal of the fourth 4-input LUT from the respective output terminals and output the signal through the respective output terminals.

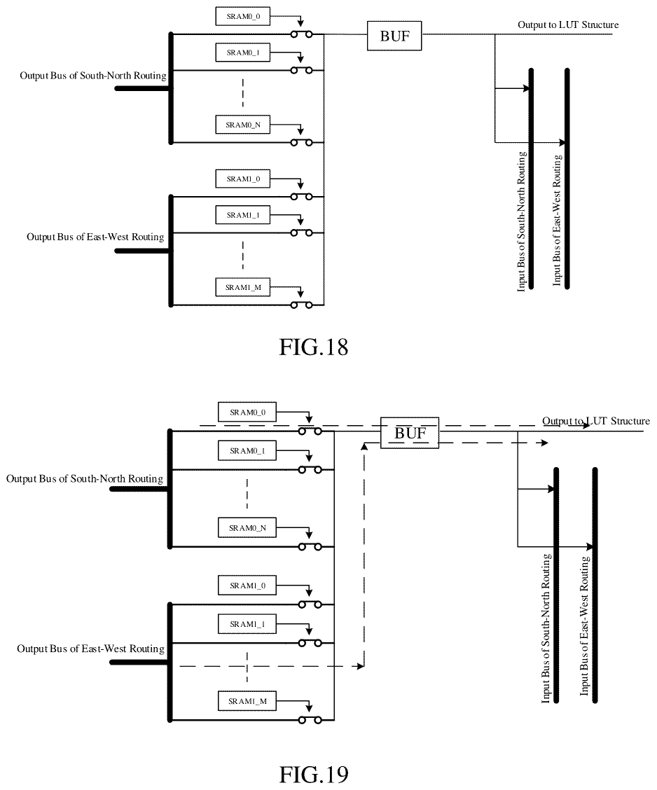

FIG. 18 is a diagram illustrating the operating mode of the MUX in the structure shown in FIG. 15. As shown in FIG. 18, the north-south routing output bus has N+1 sub-routes, and the east-west routing output bus has M+1 sub-routes, where N and M are positive integers.

In the structure shown in FIG. 18, the control signal is used to output switch control signals, which comprising the control signals respectively corresponding to the sub-routes of the north-south and east-west routing output bus;
Specifically, the control structure is SRAM, which stores the control signal SRAM0_0~N and the control signal SRAM1_0~M, wherein the control signal SRAM0_0~N controls the conduction state of the N+1 sub-routes of the north-south routing output bus, and the control signal SRAM1_0~M controls the conduction state of the M+1 sub-routes of the east-west routing output bus.

For each MUX, only one of the control signals SRAM0_0~N is set to 1 while the remaining signals are all 0, and all control signals SRAM1_0~M are 0, so that at any given moment, only one sub-route signal of the north-south routing output bus is output to the BUF; alternatively, only one of the control signals SRAM1_0~M is set to 1 while the remaining signals are 0, and all control signals SRAM0_0~N are 0, so that at any given moment, only one sub-route signal of the east-west routing output bus is output to the BUF.

Based on the above mechanisms, MUX respectively receives signals from the north-south routing output bus and the east-west routing output bus, and selects one signal to output to the LUT structure.

FIG. 19 is the first diagram illustrating the signal flow in the structure shown in FIG. 18. As shown in FIG. 19, the signal output to the LUT structure can come from the one of the sub-routes of north-south routing output bus (e.g., the sub-route corresponding to the control signal SRAM0_0) or one of the sub-routes of the east-west routing output bus (e.g., the sub-route corresponding to any signal in the control signal SRAM1_1~M).

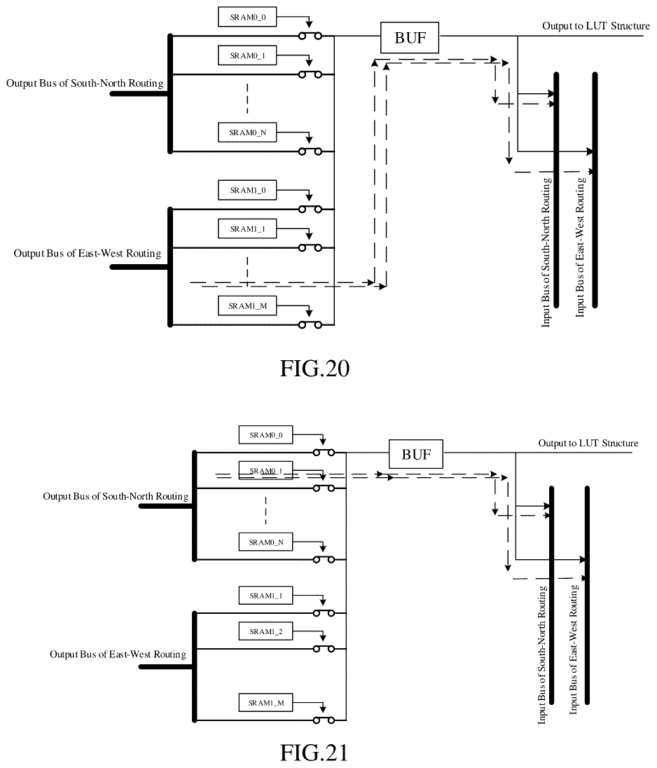

FIG. 20 is the second diagram illustrating the signal flow in the structure shown in FIG. 18. As shown in FIG. 20, one of the sub-routes of the east-west routing output bus (e.g., the sub-route corresponding to any of the control signals SRAM1_1−M) can be output to the north-south routing input bus via the BUF; or, output to the east-west routing input bus.

FIG. 21 is the third diagram illustrating the signal flow in the structure shown in FIG. 18. As shown in FIG. 20, one of the sub-routes of the north-south routing output bus (e.g., the sub-route corresponding to the control signal SRAM0_1) can be output to the north-south routing input bus via the BUF, or to the east-west routing input bus.

It can be seen from the above analysis that bridging MUX uses additional MUXes to achieve signal interconnection between different routing directions. For example, the north-south and east-west routings can exchange signals via the MUX, thereby enabling signal transmission in different directions. This design provides a high degree of flexibility, allowing dynamic selection and transmission of signals between different routings, while also enhancing the reliability and maintainability of the circuit. The specific advantages are reflected in the following aspects:
1. Resource optimization: By using MUXes, the number of required physical connections can be reduced, thereby saving space and cost.
2. Signal routing: MUXes enable flexible routing between different signal paths, which is particularly important for complex circuit designs.
3. Scalability: This design can be easily expanded to accommodate more input signals or additional routing directions.
4. Fault isolation: If a routing path or signal path fails, other paths can be selected via the MUX, thus improving system reliability.
5. Simplified design: By centralizing the control of signal selection, the overall logic design of the system is simplified, making maintenance and upgrades easier.

Those of ordinary skills in the art will recognize that some or all of the steps, systems, and functional modules/units in the devices disclosed above may be implemented as software, firmware, hardware, and suitable combinations thereof. In hardware implementations, the division between functional modules/units referred to in the above description does not necessarily correspond to the division of physical components; for example, a physical component may have more than one function, or a function/step may be cooperatively performed by several physical components. Some or all of the components may be implemented as software executed by a processor, such as a digital signal processor or microprocessor, or as hardware, or as an IC, such as ASIC. Such software may be distributed on computer-readable media, including computer storage media (or non-volatile media) and communication media (or non-volatile media). Those of ordinary skills in the art will recognize that the term computer storage medium includes volatile, non-volatile, removable, and non-removable media implemented in any method or technique for storing information, such as computer-readable instructions, data structures, program modules or other data. The computer storage medium includes, but not limited to, RAM, Read Only Memory (ROM), electrically erasable programmable read-only memory (“EEPROM”), flash memory or other memory technology, compact disc read-only memory (CD-ROM), Digital Versatile Disc (DVD), or other optical disc storage, magnetic disk, magnetic tape, magnetic disk storage, or any other media capable of storing desired information and accessible by a computer. In addition, those of ordinary skills in the art will recognize that the communication medium typically contains computer-readable instructions, data structures, program modules, or other data in a modulated data signal such as a carrier wave or other transmission mechanism, and any information delivery medium.

What is claimed is:

1. A lookup table structure, comprising four 4-input lookup tables lut 4_1, lut 4_2, lut 4_3, and lut 4_4; and three multiplexers mux 4, mux 5, and mux 7;
wherein when the lookup table structure is in 6-input lookup table mode, each 4-input lookup table receives the 4-bit data signal IN0 from the 6-input lookup table and outputs the respective output signal. The output signals of lut 4_1 and lut 4_2 are the input signals of mux 4; the output signals of lut 4_3 and lut 4_4 are the input signals of mux 5;
wherein with the control of the fifth data signal in the 6-input lookup table, mux 4 and mux 5 respectively output signals based on the input signals, which serve as the input signals for mux 7;
wherein with the control of the sixth data signal in the 6-input lookup table, mux 7 output signals based on the received input signals, which serve as the output results of the 6-input lookup table.

2. The lookup table structure of claim 1, wherein
when the lookup table structure is in 5-input lookup table mode, the lookup table structure comprising two 5-input lookup tables,
wherein both lut 4_1 and lut 4_2 receive 4-bit data signals from the first 5-input lookup table and output respective output signals; mux 4 receives output signals from lut 4_1 and lut 4_2 and outputs signals based on the received input signals, which serve as the output results of the first 5-input lookup table, with the control of the fifth data signal in the first 5-input lookup table;
wherein both lut 4_3 and lut 4_4 receive 4-bit data signals from the second 5-input lookup table and output respective output signals; mux 5 receives output signals from lut 4_3 and lut 4_4 and outputs signals based on the received input signals, which serve as the output results of the second 5-input lookup table, with the control of the fifth data signal in the second 5-input lookup table,

3. The lookup table structure of claim 2,
wherein the 4-bit data signals of lut 4_2, lut 4_3, and lut 4_4 can be switched respectively to IN0 or IN1, IN0 or IN2, and IN0, IN2, or IN3.
wherein when the lookup table structure is in 5-input lookup table mode, the 4-bit data signal of the first 5-input lookup table is IN0, and the 4-bit data signal of the second 5-input lookup table is IN2.

4. The lookup table structure of claim 2, wherein the lookup table structure further comprising a multiplexer mux 6.
The mux 6 receives the fifth data signal in the first 5-input lookup table and the fifth data signal in the second 5-input lookup table; outputs the fifth data signal in the first 5-input lookup table in 6-input lookup table mode, which serves as the control signal of mux 5; and outputs the fifth data signal in the second 5-input lookup table in 5-input lookup table mode, which serves as the control signal of mux 5.

5. The lookup table structure of claim 2,
wherein when the lookup table structure is in 4-input lookup table mode, the lookup table structure comprising four 4-input lookup tables,
wherein lut 4_1 receives 4-bit data signals and outputs signals, which serve as the output results of the first 4-input lookup table;
wherein lut 4_2 receives 4-bit data signals and outputs signals, which serve as the output results of the second 4-input lookup table;
wherein lut 4_3 receives 4-bit data signals and outputs signals, which serve as the output results of the third 4-input lookup table;
wherein lut 4_1 receives 4-bit data signals and outputs signals, which serve as the output results of the fourth 4-input lookup table.

6. The lookup table structure of claim 5,
wherein the 4-bit data signals of lut 4_2, lut 4_3, and lut 4_4 can be switched respectively to IN0 or IN1, IN0 or IN2, and IN0, IN2, or IN3;
wherein when the lookup table structure is in 4-input lookup table mode, the 4-bit data signal received by lut 4_1, lut 4_2, lut 4_3, and lut 4_4 are respectively IN0, IN1, IN2, and IN3.

7. The lookup table structure of claim 6, wherein the lookup table structure further comprising three multiplexers mux 1, mux 2, and mux 3,
wherein mux 1 receives 4-bit data signals IN0 and IN1, and when the lookup table structure is in 6-input or 5-input lookup table mode, mux 1 outputs 4-bit data signal IN0; when in 4-input lookup table mode, mux 1 outputs 4-bit data signal IN1;
wherein mux 2 receives 4-bit data signals IN0 and IN2, and when the lookup table structure is in 6-input lookup table mode, mux 2 outputs 4-bit data signal IN0; when in a mode other than 6-input lookup table mode, mux 2 outputs 4-bit data signal IN2;
wherein mux 3 receives 4-bit data signals IN0, IN2, and IN3, and when the lookup table structure is in 6-input lookup table mode, mux 3 outputs 4-bit data signal IN0; when in 5-input lookup table mode, mux 3 outputs 4-bit data signal IN2; when in 4-input lookup table mode, mux 3 outputs 4-bit data signal IN3.

8. A programmable logic unit, comprising the lookup table structure according to claim 1, wherein the carry chain structure comprising four cascaded algorithm logic units (ALUs), each ALU comprising a corresponding 4-input lookup table; wherein each ALU receives corresponding carry input signal and 4-input lookup table output signal and outputs signals.

9. The programmable logic unit of claim 8, wherein each ALU comprising a multiplexer mux 8 and an exclusive OR (XOR) unit;
wherein, for the current ALU, mux 8 receives the carry input signal of the current ALU and the output signal of the 2-input lookup table logic of the current ALU's 4-input lookup table. With the control of the output signal of the 4-input lookup table logic of the current ALU's 4-input lookup table, mux 8 outputs the carry output signal of the current ALU, which serves as one of the current ALU's output signals.
wherein, for the current ALU, the XOR unit receives the carry input signal of the current ALU and the output signal of the 4-input lookup table logic of the current ALU's 4-input lookup table and outputs the computation result signal, which serves as another output signal of the current ALU.

10. The programmable logic unit of claim 9, wherein each 4-input lookup table comprising the multiplexer mux 9 and four 2-input lookup tables;
wherein each 2-input lookup table receives the data signals of the two signal input terminals among the four signal input terminals of the 4-input lookup table and outputs respective output signals, wherein the output signal of one of the 2-input lookup tables is output to the corresponding ALU;
wherein mux 9 receives the output signals of four 2-input lookup tables and outputs signals, which serve as the output results of the 4-input lookup table logic, with the control of the data signals of the remaining two signal input terminals among the four signal input terminals of the 4-input lookup table.

11. The programmable logic unit of claim 8, further comprising a multiplexer mux 10,
wherein the mux 10 receives the output signal of the lookup table structure and the output signal of the input chain structure and multiplexes the output signal of the lookup table structure or the output signal of the carry chain structure as the output signal of the programmable logic unit.
The programmable logic unit according to any one of claims 8 to 11, further comprising the sequential logic unit;
wherein, with the control of the clock signal, the sequential logic unit outputs signals using the input signal of the sequential logic unit, wherein the input signal can be switched to the lookup table structure output signal or a preset sequential input signal.

13. The programmable logic unit of claim 12, further comprising a multiplexer mux 11,
wherein the mux 11 receives and multiplexes the output signal of the lookup table structure and the sequential input signal as the input signal of the sequential logic unit.

14. An FPGA device, further comprising the lookup table structure according to any one of claims 1 to 7 or the programmable logic unit according to any one of claims 8.

15. The FPGA device of claim 14, further comprising a multiplexing structure,
wherein one end of the multiplexing structure is connected to the east-west routing and the north-south routing, while the other end is connected to the lookup table structure, for obtaining signals from the east-west and north-south routing input bus to output the received signals to the lookup table structure as the data signals of the lookup table structure in different modes.

16. The FPGA device of claim 15, wherein the multiplexing structure set 16 multiplexers (MUXes) respectively corresponding to the sixteen signal input terminals of the lookup table structure, wherein the sixteen signal input terminals correspond to four signal input terminals for each of the four 4-bit data signals IN0, IN1, IN2, and IN3.
The input terminal of each MUX is connected to the east-west and north-south routing output buses while the output terminal is connected to the corresponding signal output terminal;
wherein, when the lookup table structure is in 6-input look-up table mode, the MUXes corresponding to four signal input terminals of 4-bit data signals IN0 receive the 4-bit data signal in 6-input look-up table mode from the respective input terminals and output the signal through the respective output terminals; Among the twelve signal input terminals of three 4-bit data signals IN1, IN2, and IN3, the MUXes corresponding to two of the signal input terminals receive the fifth and sixth data signals in 6-input look-up table mode from the respective input terminals and output the signals through the respective output terminals;
wherein, when the lookup table structure is in 5-input look-up table mode, the MUXes corresponding to four signal input terminals of 4-bit data signals IN0 receive the 4-bit data signal of the first 5-input look-up table from the respective input terminals and output the signal through the respective output terminals; the MUXes corresponding to four signal input terminals of 4-bit data signals IN2 receive the 4-bit data signal of the second 5-input look-up table from the respective input terminals and output the signal through the respective output terminals; Among the eight signal input terminals of two 4-bit data signals IN1 and IN3, the MUXes corresponding to two of the signal input terminals respectively receive the fifth data signal of the first and second 5-input look-up tables from the respective input terminals and output the signals through the respective output terminals;
wherein, when the lookup table structure is in 4-input look-up table mode, the MUXes corresponding to four signal input terminals of 4-bit data signals IN0 receive the 4-bit data signal of the first 4-input look-up table from the respective input terminals and output the signal through the respective output terminals; the MUXes corresponding to four signal input terminals of 4-bit data signals IN1 receive the 4-bit data signal of the second 4-input look-up table from the respective output terminals and output the signal through the respective output terminals; the MUXes corresponding to four signal input terminals of 4-bit data signals IN2 receive the 4-bit data signal of the third 4-input look-up table from the respective output terminals and output the signal through the respective output terminals; the MUXes corresponding to four signal input terminals of 4-bit data signals IN3 receive the 4-bit data signal of the fourth 4-input look-up table from the respective output terminals and output the signal through the respective output terminals.

17. The FPGA device of claim 16,
wherein three 4-bit data signals IN1, IN2, and IN3 comprising a total of 12 signal input terminals corresponding to 12 MUXes. Each output terminal of these 12 MUXes is connected to the corresponding signal input terminal via a connection point. These connection points is connected to two sub-routes within the east-west routing input bus, or to two sub-routes within the north-south routing input bus, or respectively to one sub-route within the north-south routing input bus and one sub-route within the east-west routing input bus;
wherein, when any signal input terminal in the lookup table structure does not require an input signal, the MUX corresponding to that signal, which is not involved in the lookup table function, acts as a bridging MUX. The bridging MUX outputs the received signal through the connection point to the sub-routes of the respective north-south and east-west routing input buses.

18. The FPGA device of claim 16, further comprising a control structure,
wherein the control structure is used to output switch control signals, which comprising the control signals respectively corresponding to the sub-routes of the north-south and east-west routing output bus;
For each MUX, among the control signals respectively corresponding to the sub-routes of the north-south and east-west routing output bus, only one control signal is valid, so that only one sub-route signal of the north-south routing output bus or the east-west routing output bus is output.
